(19) United States
(12) Patent Application Publication
(10) Pub. No.: US 2024/0146254 A1
(43) Pub. Date: May 2, 2024

(54) TRANSISTOR WITH DISTRIBUTED THERMAL FEEDBACK

(71) Applicant: TEXAS INSTRUMENTS INCORPORATED, Dallas, TX (US)

(72) Inventors: Ankur CHAUHAN, Kharapur (IN); Orlando LAZARO, Cary, NC (US); Kushal MURTHY, Bengaluru (IN); Andres BLANCO, Garland, TX (US); Henry EDWARDS, Garland, TX (US)

(21) Appl. No.: 18/050,338

(22) Filed: Oct. 27, 2022

(51) Int. Cl. H03F 1/30; H01L 27/02

(52) U.S. Cl. CPC H03F 1/308; H01L 27/0211

(57) ABSTRACT

A power transistor includes an ambient temperature input, a local temperature sensor, an array of transistor cells, and a thermal feedback circuit. The ambient temperature input is configured to receive an ambient temperature signal that is representative of an ambient temperature of the power transistor. The array of transistor cells has a control input. The local temperature sensor is configured to provide a local temperature signal that is representative of a temperature of the array of transistor cells. The thermal feedback circuit is coupled to the ambient temperature input, the local temperature sensor, and the control input. The thermal feedback circuit is configured to modulate a control signal provided at the control input based on a difference between the ambient temperature signal and the local temperature signal.

### BACKGROUND

Power switches are electronic devices used to control relatively large current flows in electrical systems. Power metal oxide semiconductor field effect transistor (MOSFETs) are one type of power switch. Power MOSFETs provide efficient current switching by connecting a large number of MOSFET cells in parallel on a die to reduce on-resistance. Power MOSFETs are used to provide current switching in a wide variety of applications. For example, power MOSFETs may be used to switch current in power supplies, DC-to-DC converters, low-voltage motor controllers, and other power switching applications.

### SUMMARY

In one example, a power transistor includes an ambient temperature input, a local temperature sensor, an array of transistor cells, and a thermal feedback circuit. The array of transistor cells has a control input. The local temperature sensor is thermally coupled to the array of transistors. The local temperature sensor has a local temperature output. The thermal feedback circuit includes a first input, a second input, and an output. The first input is coupled to the ambient temperature input. The second input is coupled to the local temperature output. The output of the thermal feedback circuit is coupled to the control input of the array of transistor cells.

In another example, a power transistor includes an ambient temperature input, a local temperature sensor, an array of transistor cells, and a thermal feedback circuit. The ambient temperature input is configured to receive an ambient temperature signal that is representative of an ambient temperature of the power transistor. The array of transistor cells has a control input. The local temperature sensor is configured to provide a local temperature signal that is representative of a temperature of the array of transistor cells. The thermal feedback circuit is coupled to the ambient temperature input, the local temperature sensor, and the control input. The thermal feedback circuit is configured to modulate a control signal provided at the control input based on a difference between the ambient temperature signal and the local temperature signal.

In a further example, an electronic fuse circuit includes a power input terminal, a power output terminal, an ambient temperature sensor, and a power transistor. The ambient temperature sensor is configured to provide an ambient temperature signal representative of an ambient temperature of the electronic fuse circuit. The power transistor is coupled between the power input terminal and the power output terminal. The power transistor includes a local temperature sensor, an array of transistor cells, and a thermal feedback circuit. The array of transistor cells has a control input. The local temperature sensor is configured to provide a local temperature signal representative of a temperature of the array of transistor cells. The thermal feedback circuit is coupled to the ambient temperature sensor, the local temperature sensor, and the control input. The thermal feedback circuit is configured to provide a control signal at the control input, and modulate the control signal based on a difference between the local temperature signal and the ambient temperature signal.

### BRIEF DESCRIPTION OF THE DRAWINGS

FIG. 1 is a block diagram for an example power transistor that includes distributed thermal feedback.

FIG. 2 is a block diagram for an example array of transistor cells suitable for use with distributed thermal feedback.

FIG. 3 is a block diagram of an example thermal feedback circuit suitable for use in the power transistor of FIG. 1.

FIG. 4 is a schematic level diagram of an example thermal feedback circuit for implementing distributed thermal feedback in a power transistor.

FIG. 5 is a schematic level diagram of an example power transistor that includes distributed thermal feedback as described herein.

FIG. 6 is a block diagram of an example system that includes multiple power transistors connected in parallel.

FIGS. 7A and 7B are graphs showing example currents flowing in power transistors without the distributed thermal feedback described herein, and with the distributed thermal feedback described herein.

FIGS. 8A and 8B are graphs showing example inrush currents flowing in parallel power transistors without the distributed thermal feedback described herein, and with the distributed thermal feedback described herein.

FIG. 9 is a block diagram of an example electronic fuse circuit.

### DETAILED DESCRIPTION

Power transistors, such as power metal oxide semiconductor field effect transistors (MOSFETs) are frequently used in applications that exhibit high power dissipation, such as high in-rush current power switches, high voltage operational amplifiers, and power amplifiers. The maximum amount of power that a transistor can safely dissipate is specified by a parameter referred to as thermal safe operating area (SOA). Thermal SOA is affected by a variety of transistor operational parameters. Thermal runaway, also known as the Spirito effect) is one limiting process that determines the thermal SOA of a transistor.

In operation, each transistor cell of a power MOSFET initially dissipates about the same amount of power. Transistor cells surrounded by other heat sources (e.g., other transistor cells) increase in temperature (relative to some other transistor cells). The increase in temperature may lower the threshold voltage of the transistor cell, which increases current flow through the transistor, and leads to higher power dissipation and higher temperature. Thermal runaway occurs when thermal loop gain is greater than one.

In high current system, multiple transistors or electronic fuse circuits may be connected in parallel to increase current capacity. However, due to the Spirito effect, the inrush current capacity of the stacked transistors is equal to the inrush capacitor of a single transistor, which, at least in part, reduce the effectiveness of the paralleled transistors.

Some power MOSFET applications attempt to prevent thermal runaway by setting an overly conservative value for maximum drain-to-source voltage. Temperature-based shutdown can also be implemented to prevent damage to the transistor, but, with temperature-based shutdown, the transistor may oscillate between operation and shutdown, which is undesirable.

The power transistors described herein subdivide the transistor cells into multiple arrays or sections. The local temperature of each array is measured compared to a measured ambient temperature of the power transistor (e.g., the average temperature of neighboring transistor arrays). The control voltage provided to the transistors cells is set based on the difference between the local temperature and the ambient temperature. For example, the control voltage provided to an array with temperature exceeding the ambient temperature is lowered to reduce the current flowing through the array and reduce the temperature of the array. Accordingly, the power transistors described herein avoid thermal runaway by reducing or eliminating thermal differences across the transistor cells.

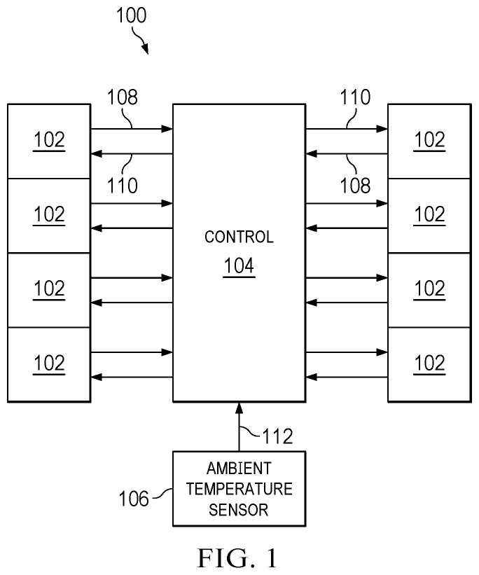

FIG. 1 is a block diagram for an example power transistor 100 that includes distributed thermal feedback. The power transistor 100 includes multiple arrays 102 of transistor cells. Each of the arrays 102 may include many (e.g., thousands) of transistor cells. While the power transistor 100 is illustrated as including eight arrays 102 in FIG. 1, various implementations of the power transistor 100 may include one or more arrays 102. Providing multiple arrays 102 in the power transistor 100 allows each of the arrays 102 to provide the better SOA characteristics of a smaller transistor, while the power transistor 100 provides the lower on-resistance of a larger transistor. However, if the threshold voltages of the different arrays 102 are mismatched (not the same), then the arrays 102 with lower threshold voltages will conduct a higher current than the arrays 102 with higher threshold voltages, leading to electrothermal positive feedback and vulnerability to thermal runaway.

The arrays 102 are coupled to a control circuit 104. The control circuit 104 generates a control signal 110 to control each of the arrays 102. For each of the arrays 102, the control circuit 104 generates the control signal 110 based on the temperature of the array 102 and an ambient temperature of the power transistor 100. The array 102 provides a local temperature measurement to the control circuit 104 via a local temperature signal 108. An ambient temperature sensor 106 is coupled to the control circuit 104 provides an ambient temperature measurement via an ambient temperature signal 112. The control circuit 104 modulates the control signal 110 based on a difference between the control signal 110 and the ambient temperature signal 112 to reduce the current flow in the arrays 102 having a temperature higher than the ambient temperature. Accordingly, the power transistor 100 equalizes the temperature across the arrays 102 to avoid thermal runaway.

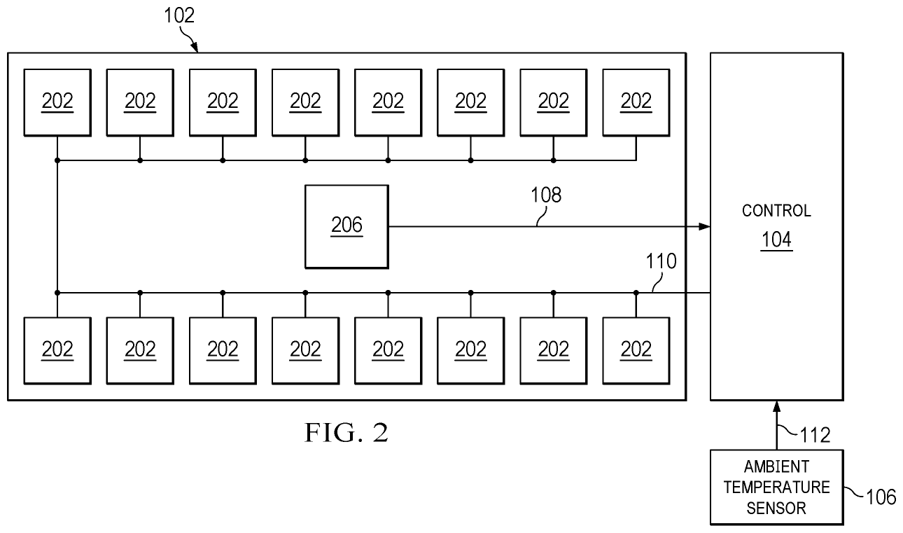

FIG. 2 is a block diagram for an example array 102 of transistor cells suitable for use with distributed thermal feedback. The array 102 includes multiple transistor cells 202 and a local temperature sensor 206. Each of the transistor cells 202 is a transistor (e.g., a MOSFET), and the transistor cells 202 are connected in parallel. The array 102 may include a large number of the transistor cells 202. While the array 102 is illustrated in FIG. 2 as including sixteen of the transistor cells 202, implementation of the array 102 may include more that sixteen of the transistor cells 202. The transistor cells 202 are coupled in parallel for receipt of the control signal 110, which is received from the control circuit 104 at a control input of the array 102. The control signal 110 may be applied to drive the gates of the transistor cells 202.

The local temperature sensor 206 may be included in the array 102, and senses the temperature of the array 102. The local temperature signal 108, which is representative of the temperature of the array 102, is provided at a local temperature output of the local temperature sensor 206. The local temperature sensor 206 is coupled to the control circuit 104 for provision of the local temperature signal 108 to the control circuit 104.

The control circuit 104 is also coupled to the ambient temperature sensor 106. The ambient temperature sensor 106 may be provided external to the array 102 as part of the power transistor 100 or may be provided external to the power transistor 100 and coupled to an ambient temperature input of the control circuit 104 (e.g., via an ambient temperature input of the power transistor 100). The ambient temperature sensor 106 senses the ambient temperature of the power transistor 100 and generates an ambient temperature signal 112 representative of the temperature of the power transistor 100 and provides the ambient temperature signal 112 at an ambient temperature output. In some implementations of the power transistor 100, the ambient temperature sensor 106 is coupled to the local temperature sensor 206 of two or more instances of the array 102, and generates the ambient temperature signal 112 as an average of the local temperature values (the local temperature signals 108) provided by the local temperature sensors. Some implementations of the ambient temperature sensor 106 generate the ambient temperature signal 112 as a constant voltage or current representing a reference temperature.

The control circuit 104 compares the ambient temperature signal 112 to the local temperature signal 108 to compare the local temperature of the array 102 to the ambient temperature of the power transistor 100. The control circuit 104 adjusts the control signal 110 provided to the array 102 based on a result of the comparison. For example, if the comparison indicates that the local temperature is higher than the ambient temperature, then the control circuit 104 may adjust the control signal (e.g., reduce the gate-to-source voltage) to reduce the current flowing through the array 102 and reduce the temperature of the array 102. If the comparison indicates that the local temperature is lower than the ambient temperature, then the control circuit 104 may adjust the control signal (e.g., increase the gate-to-source voltage) to increase the current flowing through the array 102 and increase the temperature of the array 102.

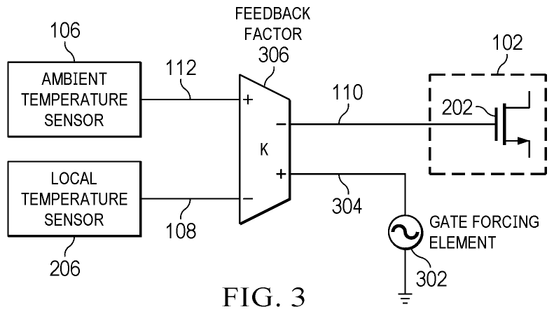

FIG. 3 is a block diagram of an example thermal feedback circuit 306 suitable for use in the power transistor 100. The thermal feedback circuit 306 may be included in the control circuit 104 to provide control for one of the arrays 102. Multiple instances of the thermal feedback circuit 306 may be provided in the control circuit 104 to control the arrays 102 (one instance of the thermal feedback circuit 306 per array 102). The thermal feedback circuit 306 compares the ambient temperature signal 112 to the local temperature signal 108 and generates an error signal representative of the difference in local and ambient temperature. The voltage source 302 provides a signal 304 (e.g., an on/off signal) for activating and deactivating the transistor cells 202. The thermal feedback circuit 306 modulates the signal 304 based on the error signal (the difference in local and ambient temperature) to provide the control signal 110 at a feedback output and control the transistor cells 202.

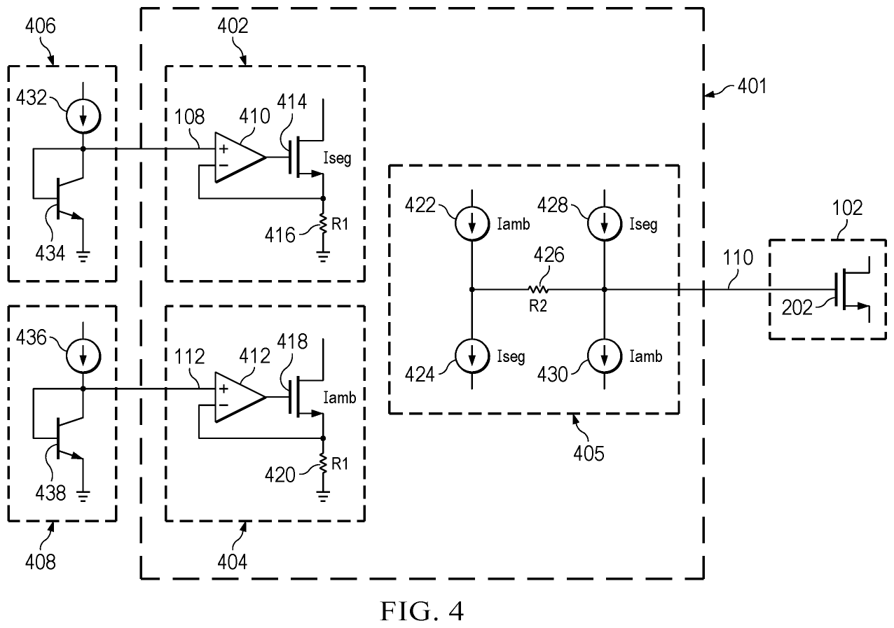

FIG. 4 is a schematic level diagram of an example thermal feedback circuit 401 suitable for implementing distributed thermal feedback in the power transistor 100. The thermal feedback circuit 401 may be included in the control circuit 104 to provide control for one of the arrays 102. The thermal feedback circuit 401 includes a feedback output, a local temperature current source 402, an ambient temperature current source 404, a thermal compensation circuit 405. The feedback output is coupled to a control input of one of the arrays 102. The local temperature current source 402 is coupled to a local temperature sensor 406 and converts the local temperature signal 108 generated by the local temperature sensor 406 to a local temperature current signal. The local temperature sensor 406 is an implementation of the local temperature sensor 206 and may be included in the array 102. The local temperature sensor 406 includes a current source 432 and a bipolar transistor 434. The bipolar transistor 434 is connected as a diode. The source of the bipolar transistor 434 is coupled to a ground terminal. The base and collector of the bipolar transistor 434 are coupled to the current source 432 and the local temperature current source 402. The voltage across the bipolar transistor 434 (a local temperature signal) varies with temperature.

The local temperature current source 402 is coupled to the local temperature sensor 406 and converts the local temperature signal 108 generated by the local temperature sensor 406 to a current (a local temperature current signal). The local temperature current source 402 includes an amplifier 410, a pass transistor 414, and a resistor 416. The pass transistor 414 may be an n-channel FET in some implementations of the local temperature current source 402. The pass transistor 414 is controlled by an output signal provided by the amplifier 410. A first amplifier input (a non-inverting input) of the amplifier 410 is coupled to the collector of the bipolar transistor 434. An amplifier output of the amplifier 410 is coupled to the control terminal (e.g., the gate) of the pass transistor 414. A first current terminal (e.g., a drain) of the pass transistor 414 is coupled to a voltage source, such as a power supply terminal. A second current terminal (e.g., a source) of the pass transistor 414 is coupled to a second amplifier input (e.g., an inverting input) of the amplifier 410. The resistor 416 is coupled between a ground terminal and the second current terminal of the pass transistor 414.

The ambient temperature sensor 408 may be similar or identical to the local temperature sensor 406. The ambient temperature sensor 408 is an implementation of the ambient temperature sensor 106 and includes a current source 436 and a bipolar transistor 438. The bipolar transistor 438 is connected as a diode. The source of the bipolar transistor 438 is coupled to a ground terminal. The base and collector of the bipolar transistor 438 are coupled to the current source 436 and the ambient temperature current source 404. The voltage across the bipolar transistor 438 (an ambient temperature signal) varies with temperature.

The ambient temperature current source 404 may be similar or identical to the local temperature current source 402. The ambient temperature current source 404 is coupled to the ambient temperature sensor 408 and converts the ambient temperature signal 112 generated by the ambient temperature sensor 408 to a current (an ambient temperature current signal). The ambient temperature current source 404 includes an amplifier 412, a pass transistor 418, and a resistor 420. The pass transistor 418 may be an n-channel FET is some implementations of the ambient temperature current source 404. The pass transistor 418 is controlled by an output signal provided by the amplifier 412. A first input (a non-inverting input) of the amplifier 412 is coupled to the collector of the bipolar transistor 438. An output of the amplifier 412 is coupled to the control terminal (e.g., the gate) of the pass transistor 418. A first current terminal (e.g., a drain) of the pass transistor 418 is coupled to voltage source, such as a power supply terminal. A second current terminal (e.g., a source) of the pass transistor 418 is coupled to second input (e.g., an inverting input) of the amplifier 412. The resistor 420 is coupled between a ground terminal and the second current terminal of the pass transistor 418.

The thermal compensation circuit 405 is coupled to the control terminal (e.g., the gate) of the transistor cells 202. The thermal compensation circuit 405 includes an ambient temperature current source 422, a local temperature current source 424, a resistor 426, a local temperature current source 428, and an ambient temperature current source 430. The local temperature current source 424 and the local temperature current source 428 may be separate instances of the local temperature current source 402, each coupled to the local temperature sensor 406. The ambient temperature current source 422 and the ambient temperature current source 430 may be instances of the ambient temperature current source 404, each coupled to the ambient temperature sensor 408. A current output of the ambient temperature current source 422 and a current input of the local temperature current source 424 are coupled to a first terminal of the resistor 426. A current output of the local temperature current source 428 and a current input of the ambient temperature current source 430 are coupled to a second terminal of the resistor 426. Differences in the local temperature current signals and the ambient temperature current signals determine the direction of current flow through the resistor 426, which increases or decreases the control voltage applied to the transistor cells 202. For example, if the ambient temperature current signal is greater than the local temperature current signal (the ambient temperature of the power transistor 100 is greater than the temperature of the array 102), then current flows to the transistor cells 202 through the resistor 426 to increase the control voltage of the transistor cells 202. If the local temperature current signal is greater than the ambient temperature current signal (the temperature of the array 102 is greater than the ambient temperature of the power transistor 100), then current flows from the transistor cells 202 through the resistor 426 to decrease the control voltage of the transistor cells 202.

The magnitude of the thermal feedback gain in the thermal feedback circuit 401 depends on the ratio of the resistances

$$\frac{R 2}{R 1}$$

of the resistors 426, 416, and 420, where R2 is the resistance of the resistor 426, and the resistor 416 and the resistor 420 have a same resistance R1. The greater the value of ratio

$$\frac{R 2}{R 1} ,$$

the greater the reduction in current to the transistor cells 202 with increase in temperature, and the greater the thermal robustness of the power transistor 100. If the value of ratio

$$\frac{R 2}{R 1}$$

is too great, the power up time of the power transistor 100 may increase, due to the strong reduction in gate charging current to the transistor cells 202. In implementations of the power transistor 100, the values of the resistors 426, 416, and 420 are selected such that the value of ratio

$$\frac{R 2}{R 1}$$

is greater than the gain needed to keep the transistor cells 202 within the safe operating area for maximum power dissipation, and the value of ratio

$$\frac{R 2}{R 1}$$

is less than the gain above which a predetermined power up time is exceeded.

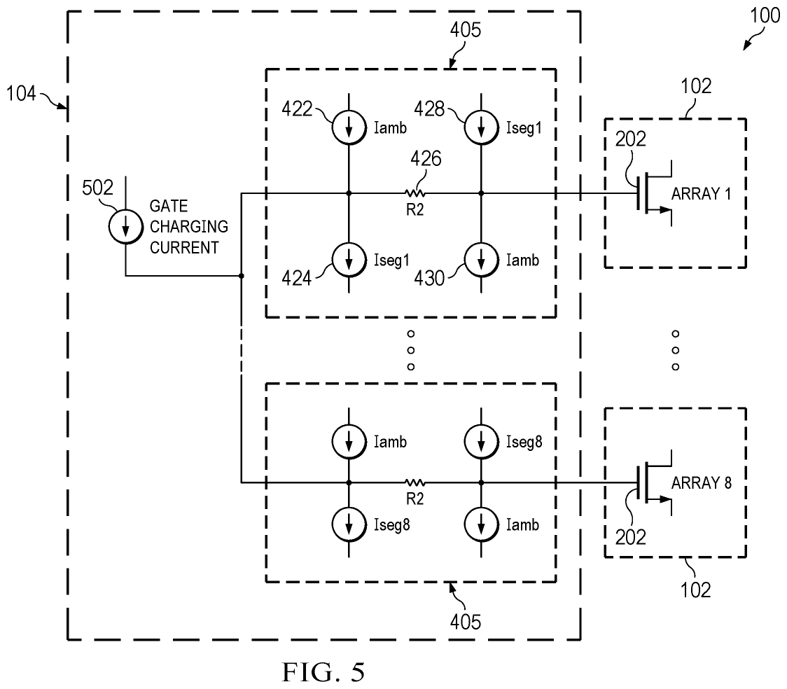

FIG. 5 is a schematic level diagram of the power transistor 100. The power transistor 100 includes one or more arrays 102. The control circuit 104 includes an instance of the thermal compensation circuit 405 coupled to each instance of the array 102. The thermal compensation circuit 405 adjusts the control signal 110 provided to the array 102 based on a difference in ambient and local temperature. A current source 502 is coupled to the thermal compensation circuits 405 in parallel. Accordingly, the current supplied to all of the thermal compensation circuit 405 combined remains constant, while the current provided to an individual array 102 is varied with temperature. As thermal feedback is initiated by the thermal compensation circuit 405, the control current provided to higher current carrying arrays 102 is reduced. In turn, the control current provided to lower current carrying arrays 102 increases. Via such operation, the thermal feedback reduces the difference in current through the arrays 102 and maintains the thermal equilibrium of the power transistor 100.

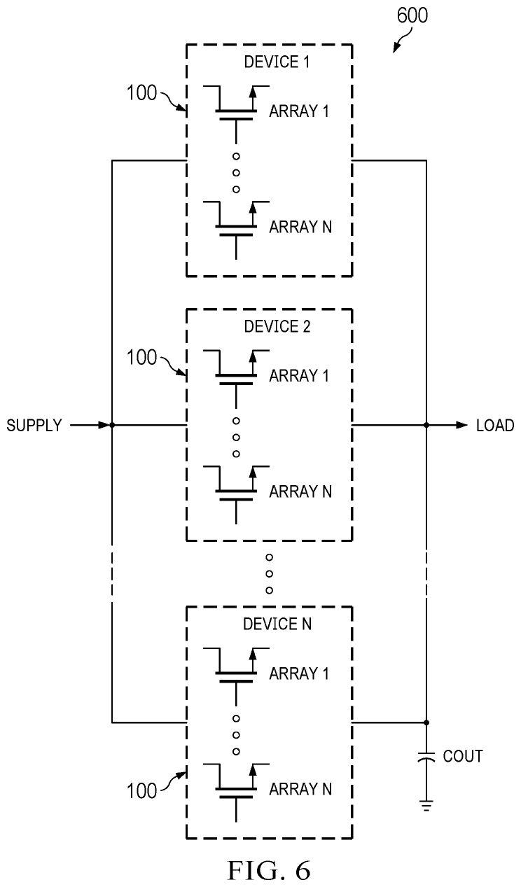

FIG. 6 is a block diagram of an example system 600. To meet the high current requirements of the system 600, the system 600 includes multiple power transistor 100 connected in parallel. The system 600 includes three instances of the power transistor 100 connected in parallel. Other implementations of the system 600 may include 2 or more instances of the power transistor 100 connected in parallel. Without the distributed thermal feedback of the power transistor 100, mismatch among the transistors may cause a continuous increase in current skew that is likely to make one of the transistors carry most of the system current, leading to shut-down of the transistor by the transistor's thermal shut-down mechanism. The operation of the power transistor 100 causes a reduction in current through the transistor that is dissipating the highest power, which causes an increase in current through the power transistors to maintain total system current. The power transistor 100 reduces overall skew among different instances of the power transistor 100, providing more uniform distribution of current without external communication between the instances of the power transistor 100.

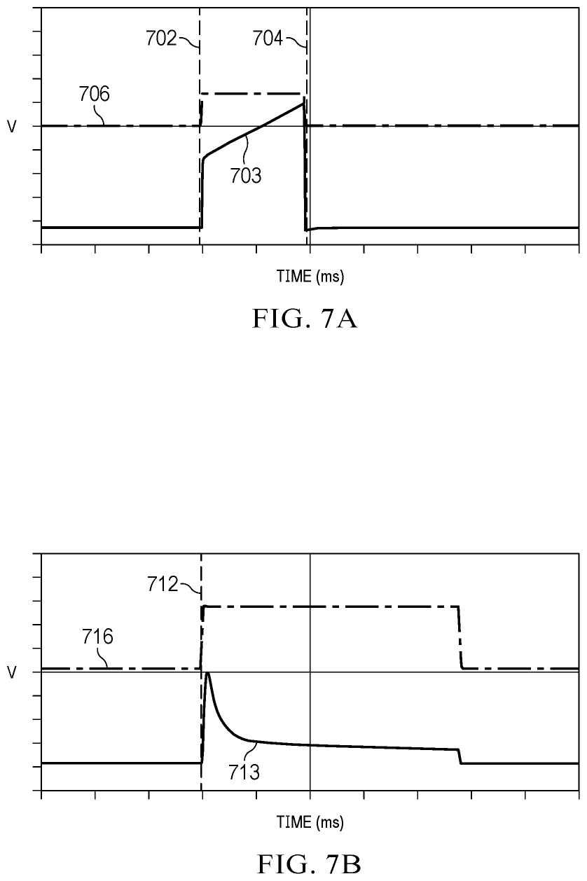

FIGS. 7A and 7B are graphs showing example currents flowing in power transistors without the distributed thermal feedback described herein, and with the distributed thermal feedback described herein. FIG. 7A shows an example of current flow in a power transistor that lacks the distributed thermal feedback of the power transistor 100. At time 702, the gate voltage 706 rises to turn on the transistor, and current 703 flowing through the transistor increases in a step. Thereafter, due to the Spirito effect, the current 703 through the transistor increases as the transistor's temperature increases. The current 703 increases until thermal shutoff circuitry turns the transistor off at time 704.

FIG. 7B show example operation of the power transistor 100. At time 712, the gate voltage 706 rises to turn on the transistor, and current 713 flowing through the transistor increases in a step. Rather than continuing to rise, as in FIG. 7A, the distributed thermal feedback circuitry of the power transistor 100 reduces the current flow through the power transistor 100 to equalize the temperature across the arrays 102 of the power transistor 100. The distributed thermal feedback allows the power transistor 100 to operate the higher gate-to-source voltage than other power transistor implementations. Higher values of thermal feedback allow use of higher values of gate-to-source voltage. For example, the power transistor 100 may operate with a gate-to-source voltage of up to 4.1 volts with a high value of thermal feedback (e.g., 24 mV/° C.) versus a gate-to-source voltage of 1.43 volts with no thermal feedback.

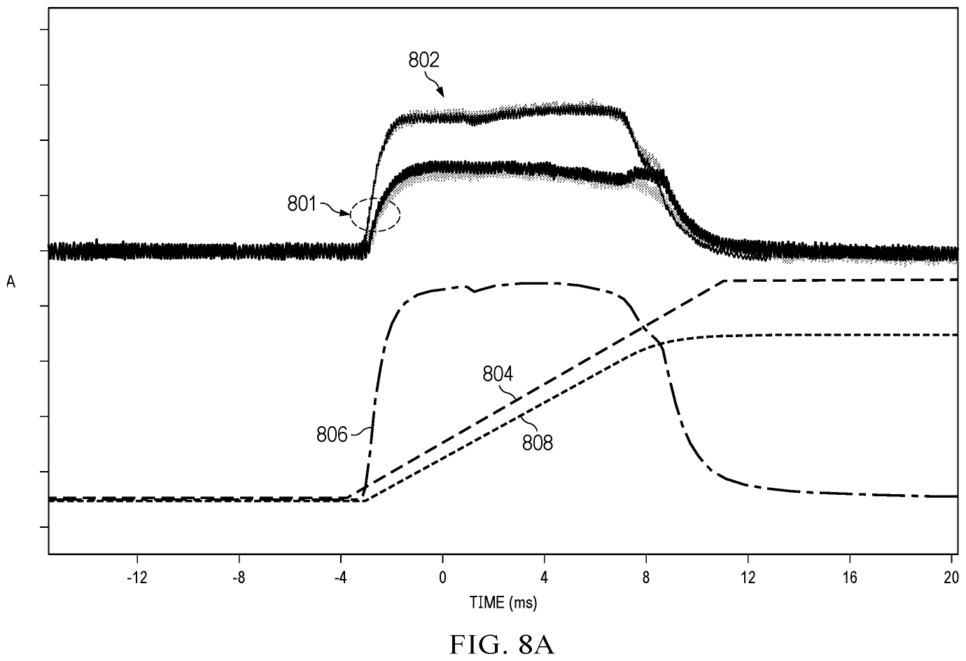

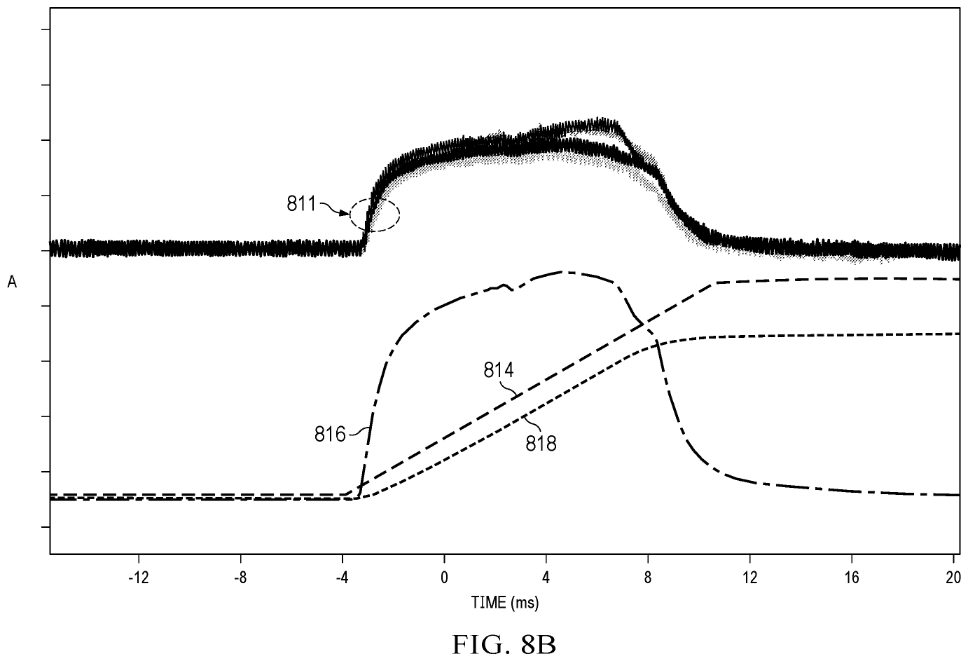

FIGS. 8A and 8B are graphs showing example inrush currents flowing in five parallel power transistors without the distributed thermal feedback described herein, and with the distributed thermal feedback described herein. An offset voltage has been applied to the gate voltage of two of the power transistors to simulate threshold voltage mismatch. FIG. 8A shows inrush currents 801 flowing in the five parallel power transistors without the distributed thermal feedback. The gate voltage 804, output voltage 808, and total current 806 flowing through the five parallel power transistors is shown in FIGS. 8A and 8B. The current 802 flowing in the power transistors with added gate voltage offset is substantially higher than the current flowing in the other three power transistors.

FIG. 8B shows the inrush currents 811 flowing in the five parallel power transistors 100 with distributed thermal feedback. The gate voltage 814, output voltage 818, and total current 816 flowing through the five parallel power transistors 100 is shown in FIG. 8B. In FIG. 8B, the distributed thermal feedback circuitry of the power transistors 100 reduces the inrush current 801 flowing through the power transistors 100 with the added gate voltage to equalize the current flowing through five power transistors 100.

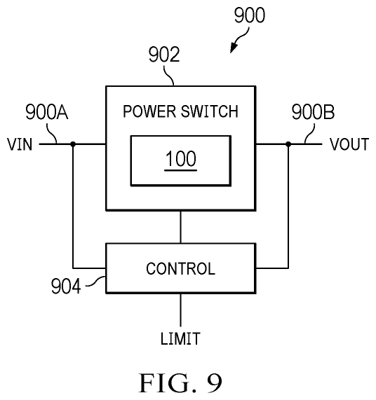

FIG. 9 is a block diagram of an example electronic fuse circuit 900. The electronic fuse circuit 900 may be used in applications that implement hot swapping of system components, or that switch based on current or power thresholds. For example, the electronic fuse circuit 900 may be used to couple server components to a power supply or to couple networking system components to a backplane or other system connector. The electronic fuse circuit 900 includes a power input terminal 900A, a power output terminal 900B, a power switch 902, and a control circuit 904. The power switch 902 is coupled between the power input terminal 900A and the power output terminal 900B, and switches current from the power input terminal 900A to the power output terminal 900B. The power switch 902 includes one or more power transistors 100 to switch the current. Use of the power transistor 100 enables the electronic fuse circuit 900 to prevent thermal runaway that might damage or degrade the operation of the electronic fuse circuit 900.

The control circuit 904 is coupled to the power input terminal 900A and the power output terminal 900B, and monitors the voltages on the power input terminal 900A and the power output terminal 900B. The control circuit 904 is coupled to a control input of the power switch 902. The control circuit 904 provides a control signal for controlling the power switch 902. For example, the control circuit 904 provides a gate drive signal for turning the power transistor 100 on or off. The control circuit 904 includes a limit input for setting a current or power threshold at which the control circuit 904 deactivates the power switch 902.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “n,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” means that the conduction channel of the FET is present and drain current may flow through the FET. References herein to a FET being “off” means that the conduction channel is not present and drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A power transistor, comprising:
an ambient temperature input;
an array of transistor cells having a control input;
a local temperature sensor having a local temperature output, the local temperature sensor thermally coupled to the array of transistor cells; and
a thermal feedback circuit including:
a first input coupled to the ambient temperature input;
a second input coupled to the local temperature output; and
a feedback output coupled to the control input.

2. The power transistor of claim 1, wherein:
the array of transistor cells is a first array of transistor cells;
the control input is a first control input;
the local temperature sensor is a first local temperature sensor;
the local temperature output is a first local temperature output;
the thermal feedback circuit is a first thermal feedback circuit;
the feedback output is a first feedback output; and
the power transistor includes:
a second array of transistor cells having a second control input;
a second local temperature sensor having a second local temperature output, the second local temperature sensor thermally coupled to the second array of transistors; and
a second thermal feedback circuit including:
a third input coupled to the ambient temperature input;
a fourth input coupled to the second local temperature output; and
a second feedback output coupled to the second control input.

3. The power transistor of claim 1, wherein the thermal feedback circuit includes:
a resistor including:
a first terminal coupled to the control input; and
a second terminal;
an ambient temperature current source having a current output coupled to the second terminal; and
a local temperature current source having a current input coupled to the second terminal.

4. The power transistor of claim 3, wherein:
the ambient temperature current source is a first ambient temperature current source;
the local temperature current source is a first local temperature current source;
the current input is a first current input;
the current output is a first current output; and
the thermal feedback circuit includes:
a second ambient temperature current source having a second current input coupled to the first terminal; and
a second local temperature current source having a second current output coupled to the first terminal.

5. The power transistor of claim 3, wherein:
the resistor is a first resistor; and
the local temperature current source includes:
an amplifier including:
a first amplifier input coupled to the local temperature output;
a second amplifier input; and
an amplifier output;
a first transistor including:
a first control terminal coupled to the amplifier output; and
a first current terminal coupled to the second amplifier input; and
a second resistor coupled between the first current terminal and a ground terminal.

6. The power transistor of claim 5, wherein:
the amplifier is a first amplifier; and
the ambient temperature current source includes:
a second amplifier including:
a third amplifier input coupled to the ambient temperature input;
a fourth amplifier input; and
a second amplifier output;
a second transistor including:
a second control terminal coupled to the second amplifier output; and
a second current terminal coupled to the fourth amplifier input; and
a third resistor coupled between the second current terminal and the ground terminal.

7. The power transistor of claim 6, wherein:
the second resistor and the third resistor have approximately a same resistance; and
the first resistor has greater resistance than the second resistor.

8. The power transistor of claim 1, further comprising an ambient temperature sensor coupled to the ambient temperature input.

9. A power transistor, comprising:
an ambient temperature input;
an array of transistor cells having a control input;
a local temperature sensor configured to provide a local temperature signal representative of a temperature of the array of transistor cells; and
a thermal feedback circuit coupled to the ambient temperature input, the local temperature sensor, and the control input, the thermal feedback circuit configured to:
provide a control signal at the control input; and
modulate the control signal based on a difference between the local temperature signal and an ambient temperature signal representative of an ambient temperature of the power transistor received at the ambient temperature input.

10. The power transistor of claim 9, wherein:
the array of transistor cells is a first array of transistor cells;
the local temperature sensor is a first local temperature sensor;
the local temperature signal is a first local temperature signal;
the thermal feedback circuit is a first thermal feedback circuit;
the control signal is a first control signal;
the control input is a first control input; and
the power transistor includes:
a second array of transistor cells having a second control input;
a second local temperature sensor configured to provide a second local temperature signal representative of a temperature of the second array of transistor cells; and
a second thermal feedback circuit coupled to the ambient temperature input, the second local temperature sensor, and the second control input, the second thermal feedback circuit configured to modulate a second control signal at the second control input based on a difference between the second local temperature signal and the ambient temperature signal.

11. The power transistor of claim 9, wherein the thermal feedback circuit includes an ambient temperature current source coupled to the ambient temperature input, the ambient temperature current source configured to provide an ambient temperature current that is representative of the ambient temperature of the power transistor.

12. The power transistor of claim 11, wherein the ambient temperature current source includes:
an amplifier having a first amplifier input, a second amplifier input, and an amplifier output, the first amplifier input coupled to the ambient temperature input;
a transistor having a control terminal and a current terminal, in which the control terminal is coupled to the amplifier output and the current terminal is coupled to the second amplifier input, and the transistor is configured to conduct the ambient temperature current based on an amplifier output signal provided at the control terminal; and
a resistor coupled between a ground terminal and to the current terminal, the resistor configured to conduct the ambient temperature current.

13. The power transistor of claim 11, wherein the thermal feedback circuit includes a local temperature current source coupled to the local temperature sensor, the local temperature current source configured to provide a local temperature current that is representative of the temperature of the array of transistor cells.

14. The power transistor of claim 13, wherein the local temperature current source includes:
an amplifier having a first amplifier input, a second amplifier input, and an amplifier output, the first amplifier input coupled to the local temperature sensor;
a transistor having a control terminal and a current terminal, in which the control terminal is coupled to the amplifier output and the current terminal is coupled to the second amplifier input, and the transistor is configured to conduct the local temperature current based on an amplifier output signal provided at the control terminal; and
a resistor coupled between a ground terminal and to the current terminal, the resistor configured to conduct the local temperature current.

15. The power transistor of claim 13, wherein the thermal feedback circuit includes a resistor having a first terminal coupled to the ambient temperature current source and the local temperature current source, the resistor configured to conduct a current representative of the difference between the ambient temperature of the power transistor and the temperature of the array of transistor cells.

16. The power transistor of claim 15, wherein:
the ambient temperature current source is a first ambient temperature current source;
the local temperature current source is a first local temperature current source;
the thermal feedback circuit includes;
a second ambient temperature current source coupled to a second terminal of the resistor; and
a second local temperature current source coupled to the second terminal of the resistor.

17. The power transistor of claim 9, further comprising an ambient temperature sensor coupled to the ambient temperature input, the ambient temperature sensor configured to sense the ambient temperature of the power transistor and provide the ambient temperature signal.

18. An electronic fuse circuit, comprising:
a power input terminal;
a power output terminal;
an ambient temperature sensor configured to provide an ambient temperature signal representative of an ambient temperature of the electronic fuse circuit; and
a power transistor coupled between the power input terminal and the power output terminal, the power transistor including:
an array of transistor cells having a control input;
a local temperature sensor configured to provide a local temperature signal representative of a temperature of the array of transistor cells; and
a thermal feedback circuit coupled to the ambient temperature sensor, the local temperature sensor, and the control input, the thermal feedback circuit configured to:
provide a control signal at the control input; and
modulate the control signal based on a difference between the local temperature signal and the ambient temperature signal.

19. The electronic fuse circuit of claim 18, wherein:
the array of transistor cells is a first array of transistor cells;
the local temperature sensor is a first local temperature sensor;
the local temperature signal is a first local temperature signal;
the thermal feedback circuit is a first thermal feedback circuit;
the control signal is a first control signal;
the control input is a first control input; and
the power transistor includes:
a second array of transistor cells having a second control input;
a second local temperature sensor configured to provide a second local temperature signal representative of a temperature of the second array of transistor cells; and
a second thermal feedback circuit coupled to the ambient temperature sensor, the second local temperature sensor, and the second control input, the second thermal feedback circuit configured to modulate a second control signal provided at the second control input based on a difference between the second local temperature signal and the ambient temperature signal.

20. The electronic fuse circuit of claim 18, wherein the thermal feedback circuit includes:
a first ambient temperature current source coupled to the ambient temperature sensor, the first ambient temperature current source configured to generate a first ambient temperature current that is representative of the ambient temperature of the electronic fuse circuit;
a second ambient temperature current source coupled to the ambient temperature sensor, the second ambient temperature current source configured to generate a second ambient temperature current that is representative of the ambient temperature of the electronic fuse circuit;
a first local temperature current source coupled to the local temperature sensor, the first local temperature current source configured to generate a first local temperature current that is representative of the temperature of the array of transistor cells; and
a second local temperature current source coupled to the local temperature sensor, the second local temperature current source configured to generate a second local temperature current that is representative of the temperature of the array of transistor cells.

21. The electronic fuse circuit of claim 20, wherein the thermal feedback circuit includes a resistor having:
a first terminal coupled to the first ambient temperature current source and the first local temperature current source; and
a second terminal coupled to the second ambient temperature current source and the second local temperature current source.

22. The electronic fuse circuit of claim 21, wherein the second terminal of the resistor is coupled to the control input of the array of transistor cells.
